(19) United States
(12) Patent Application Publication
(10) Pub. No.: US 2007/0145415 A1
(43) Pub. Date: Jun. 28, 2007

(54) High-frequency semiconductor device

(75) Inventors: Akira Inoue, Tokyo (JP); Hirotaka Amasuga, Tokyo (JP); Tetsuo Kunii, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Electric Corporation, Tokyo (JP)

(21) Appl. No.: 11/484,624

(22) Filed: Jul. 12, 2006

(30) Foreign Application Priority Data
Dec. 22, 2005 (JP) 2005-369677

(51) Int. Cl. H01L 29/76

(52) U.S. Cl. 257/213

(57) ABSTRACT

A semiconductor device operating at a frequency between 0.8 GHz and 300 GHz includes an active region that is positioned on a semi-insulating GaAs substrate; a gate electrode that is positioned in the active region; and a source electrode and a drain electrode that are positioned on the surface of the active region facing each other with the gate electrode positioned between the source electrode and the drain electrode. A drain side active region, which is a part of the active region and positioned between the gate electrode and the drain electrode, increases in width in the direction to the drain electrode from the gate electrode.

### BACKGROUND OF THE INVENTION

1. Field of the Invention

The present invention relates to a high-frequency semiconductor device, and more particularly to a field-effect high-frequency semiconductor device that operates at a high frequency between 0.8 GHz and 306 GHz and is especially used as a power amplifier.

2. Description of the Related Art

An SSPA (Solid State Power Amplifier) is widely used in wireless communication systems for satellite communications and terrestrial microwave communications. Conventionally, GaAs-based, field-effect transistors are used as 3 GHz or higher frequency SSPA transistors. In recent years, it is increasingly demanded that a large amount of information is transmitted due to the development of broadband communications. To increase the information transmission amount in accordance with such demand, it is necessary to raise the transmission rate. Thus, there is now an increased demand for an SSPA that is used in a high-frequency band. More specifically, a high-gain, high-efficiency, high-output transistor is now demanded.

As an internal adjustment type, high-frequency, high-output FET that meets the above demand, a p-HEMT is used (the n-conduction type, the p-conduction type, and the type that is free from particular impurity insertions are hereinafter prefixed by “n−”, “p−”, and “i−”, respectively). A conventional p-HEMT has been improved for higher performance as a low-noise amplification transistor. Recently, however, a field-effect transistor with a large voltage withstanding capacity and high-output is being developed as a power amplifier.

In a known example of the above-mentioned field-effect transistor, for instance, paragraph 0022 and FIG. 8 in Japanese Patent Laid-Open No. 2005-159157, patterning is performed to reduce the HEMT element size so that the gate electrode is a continuous line within the chip region, extended in the up-down direction as viewed in the figure between the source electrode and drain electrode, and extended in the left-right direction in the other area.

In another known example, for instance, paragraphs 0003, 0009, and 0010 and FIGS. 3 and 4 in Japanese Patent Laid-Open No. 2001-60684, a discontinuous cap layer is provided between the gate and drain electrodes of an HEMT in order to provide a high-frequency, compound semiconductor, field-effect transistor with a large voltage withstanding capacity and a good high-frequency characteristic.

In another known example, for instance, paragraphs 0016 and 0017 and FIG. 1 in Japanese Patent Laid-Open No. 1993-129344, a field-effect transistor includes a gate electrode, a source electrode, and a drain electrode. The gate electrode is provided on a side surface of a recess. The source electrode is provided on a flat surface of a substrate near the recess provided with the gate electrode. The drain electrode is formed at the bottom of the recess. Thus, the gate electrode is formed near the source electrode although the distance between the source electrode side edge of the recess and the source electrode remains unchanged. Therefore, the source parasitic resistance is greatly reduced. Further, the horizontal component of an electric field in a channel directly below the gate electrode is rendered smaller and subdued by the vertical component of an area including the bottom of the recess. Consequently, the gate-to-drain voltage withstanding capacity increases.

In another known example, for instance, paragraphs 0008, 0030, and 0033 and FIGS. 1 and 3 in Japanese Patent Laid-Open No. 2000-21900, an offset gate structure in which the recess width between the gate and source differs from the recess width between the gate and drain is employed as a T-gate structure. In this example, the gate-to-drain voltage withstanding capacity can be increased by forming asymmetric T-type electrodes and making the parasitic capacitance generated under an overhang of the T-type electrode on the drain side smaller than that on the source side or by providing the source side with a one-step recess etching shape and the drain side with a two-step recess etching shape.

In still another known example, for instance, H. Amasuga et al., “A High Power Density TaN/Au T-gate PHEMT with High Humidity Resistance for Ka-Band Applications”, IEEE IMS2005 Digest, June 2005, a high-output p-HEMT is described in detail. This p-HEMT uses an offset gate structure that includes a T-gate.

When the gate-to-drain distance Lrd in the field-effect transistor described above is long, the electric field between the gate and drain is generally subdued. Thus, the gate-to-drain voltage withstanding capacity Vgd0 increases. However, when a high frequency of approximately 14 GHz is used, the output power of a p-HEMT or other field-effect transistor lowers.

When, for instance, the output power P1dB (W/mm) was measured with p-HEMTs differing in the gate-to-drain distance Lrd subjected to a load pull at 14 GHz, that is, with the output impedance varied, the output power P1dB was approximately 0.78 W/mm when Lrd=0.45 μm and approximately 0.25 W/mm when Lrd=2.05 μm. Further, the gate-to-drain distance Lrd was varied in 0.4 μm increments from 0.45 μm to 2.05 μm when measurements were made. The results obtained from the measurements indicate that the output power P1dB decrease virtually linearly when the gate-to-drain distance Lrd increased from 0.45 μm to 2.05 μm.

When the gate-to-drain distance Lrd increases, the drain parasitic resistance Rd slightly increases; however, the above-mentioned output power drastically decreases as compared to the slight increase in the parasitic resistance Rd.

In particular, the output power decrease due to an increase in the gate-to-drain distance Lrd is slight at a relatively low frequency of 1 GHz. However, the output power considerably decreases with an increase in the frequency.

The above problem can be avoided by decreasing the gate-to-drain distance Lrd. In such an instance, however, the gate-to-drain voltage withstanding capacity Vgd0 decreases so that the operation cannot be performed at a high voltage. Consequently, the output power cannot be increased.

### SUMMARY OF THE INVENTION

The present invention has been made to solve the above problem. It is a first object of the present invention to provide a high-frequency semiconductor device that is capable of increasing its output power without decreasing the gate-to-drain voltage withstanding capacity.

According to one aspect of the invention, there is provided a high-frequency semiconductor device operating at a high frequency between 0.8 GHz and 300 GHz according to the present invention comprises: a semi-insulating semiconductor substrate; an active region located on the semiconductor substrate, the active region including a channel layer composed of a conductive type semiconductor layer; a gate electrode located on the active region; and a source electrode and a drain electrode on the surface of the active region, opposed to each other with the gate electrode between the source electrode and the drain electrode; wherein the active region have a first region being a part between the gate electrode and the drain electrode, and wherein the first region has a width increasing in correspondence with a distance from the gate electrode in the direction to the drain electrode.

Accordingly, in the high-frequency semiconductor device according to the present invention, the maximum current increases in proportion to an increase in the width of the drain electrode in the first region, thereby a large current is supplied to an FET that is constituted by the gate electrode even if a pseudo FET generates in the first region. Therefore, it is possible to inhibit the output power from decreasing. This makes it possible to configure a high-frequency semiconductor device having a large voltage withstanding capacity and increased output power.

Other objects and advantages of the invention will become apparent from the detailed description given hereinafter. It should be understood, however, that the detailed description and specific embodiments are given by way of illustration only since various changes and modifications within the scope of the invention will become apparent to those skilled in the art from this detailed description.

### BRIEF DESCRIPTION OF THE DRAWINGS

FIG. 1 is a plan view illustrating a high-frequency semiconductor device according to an embodiment of the present invention.

FIG. 2 is a cross-sectional view that is taken along section II-II of FIG. 1 to illustrate the high-frequency semiconductor device.

FIG. 3 is a circuit diagram to show a p-HEMT equivalent circuit that is formed in consideration of a pseudo FET for the high-frequency semiconductor device according to an embodiment of the present invention.

FIG. 4 is a plan view illustrating a modified version of the high-frequency semiconductor device according to one embodiment of the present invention.

FIG. 5 is a plan view illustrating a high-frequency semiconductor device according to one embodiment of the present invention.

FIG. 6 is a cross-sectional view that is taken along section VI-VI of FIG. 5 to illustrate the high-frequency semiconductor device.

FIG. 7 is a plan view illustrating a modified version of the high-frequency semiconductor device according to one embodiment of the present invention.

FIG. 8 is a plan view illustrating a high-frequency semiconductor device according to one embodiment of the present invention.

FIG. 9 is a plan view illustrating a modified version of the high-frequency semiconductor device according to one embodiment of the present invention.

FIG. 10 is a plan view illustrating another modified version of the high-frequency semiconductor device according to one embodiment of the present invention.

FIG. 11 is a plan view illustrating still another modified version of the high-frequency semiconductor device according to one embodiment of the present invention.

FIG. 12 is a cross-sectional view that is taken along section XII-XII of FIG. 11 to illustrate the high-frequency semiconductor device.

FIG. 13 is a plan view illustrating a high-frequency semiconductor device according to one embodiment of the present invention.

FIG. 14 is a plan view illustrating a high-frequency semiconductor device according to one embodiment of the present invention.

In all figures, the substantially same elements are given the same reference numbers.

### DESCRIPTION OF THE PREFERRED EMBODIMENTS

### First Embodiment

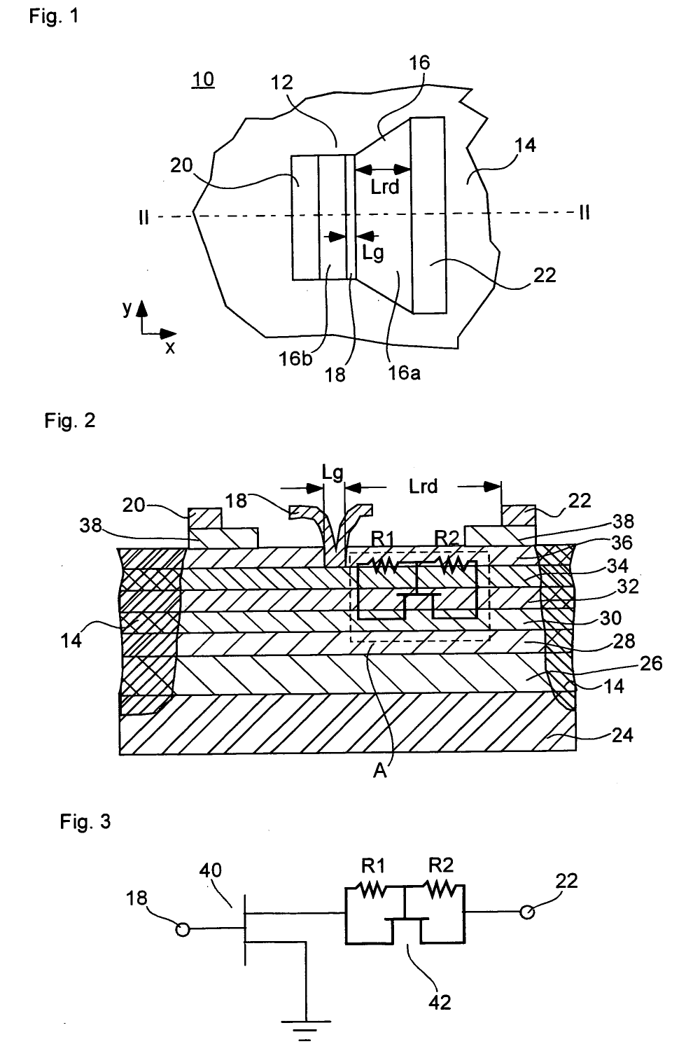

FIG. 1 is a plan view illustrating a high-frequency semiconductor device according to an embodiment of the present invention. FIG. 2 is a cross-sectional view that is taken along section II-II of FIG. 1 to illustrate the high-frequency semiconductor device. In the below-mentioned drawings, like reference numerals denote like elements.

A p-HEMT 10, which serves as a high-frequency semiconductor element for use in a high-frequency semiconductor device and shown in FIG. 1, is used as a solid state power amplifier in a wireless communication system for satellite communications, terrestrial microwave communications, or the like. This p-HEMT 10 is an internally consistent, high-frequency, high-power FET and mainly used at a frequency of 14 GHz or higher. It generates an output of 0.5 W or more for a gate width of 1 mm. In the internally consistent type, the high-frequency semiconductor element within a package includes an internally consistent substrate outside the element.

In the p-HEMT shown in FIGS. 1 and 2, an element region 12 is surrounded by an inactive region 14.

In the element region 12, a gate electrode 18 is positioned over an active region 16, which includes a channel layer 30 (the channel layer 30 will be described later with reference to FIG. 2). A source electrode 20 and a drain electrode 22 are positioned over the active region 16 to face each other. A gate electrode 18 is positioned between the source electrode 20 and drain electrode 22.

A contact layer 38 that is shown in FIG. 2 is omitted from FIG. 1. The upper layer of a T-electrode is omitted from the gate electrode 18 shown in FIG. 1, and only the lower layer of a T-leg, which is joined to the active region 16, is shown. This illustration method also applies to all subsequent plan views.

In FIG. 1, the gate width of the gate electrode 18 is y-direction length, and the gate length Lg is x-direction length.

The active region between the gate electrode 18 and drain electrode 22 is a drain side active region 16a, which serves as a first region. The active region between the gate electrode 18 and source electrode 20 is a source side active region 16b.

When the gate-to-drain distance Lrd is long, the electric field between the gate and drain is generally subdued so that the gate-to-drain voltage withstanding capacity Vgd0 increases. For example, the gate-to-drain distance Lrd in the p-HEMT 10 ranges from 0.1 micrometer to several tens of micrometers. When the drain side active region 16a and source side active region 16b are put together, the gate-to-drain distance Lrd ranges from 0.3 micrometer to several tens of micrometers.

In the p-HEMT 10, for example, the gate length Lg is 0.3 μm, and the gate width is approximately 60 μm.

Further, in the p-HEMT 10, the source resistance is decreased to increase the gate-to-drain voltage withstanding capacity Vgd0 by reducing the distance between the gate electrode 18 and source electrode 20 and by making the distance Lrd between the gate electrode 18 and drain electrode 22 longer than the distance between the gate electrode 18 and source electrode 20.

Furthermore, in the present embodiment, the width (y-direction length) of the source side active region 16b is equal to the electrode widths of the gate electrode 18 and source electrode 20. However, the width (y-direction length) of the drain side active region 16a increases continuously from the width of the gate electrode 18 to the width of the drain electrode 22 in the direction from the gate electrode 18 to the drain electrode 22, that is, increases continuously with a decrease in the distance to the drain electrode 22.

FIG. 2 shows a multilayer structure of the p-HEMT 10.

The p-HEMT 10 is formulated by sequentially positioning a buffer layer 26, a lower electron supply layer 28, which is formed by n-AlGaAs, a channel layer 30, which is formed by i-InGaAs, an upper electron supply layer 32, which is formed by n-AlGaAs, and a Schottky layer 34, which is formed by i-AlGaAs, over a semi-insulating GaAs substrate 24, which serves as a semiconductor substrate. The T-gate electrode 18 is Schottky-junctioned to the surface of the Schottky layer 34.

Further, a cap layer 36, which is formed on the surface of the Schottky layer 34 by i-GaAs, is positioned to cover the lower layer of the Schottky-junctioned gate electrode leg.

The contact layer 38, which is formed by n-GaAs, is positioned in the source region and drain region over the surface of the cap layer 36. Further, the source electrode 20 and drain electrode 22 are positioned over the contact layer 38 to form a double-hetero p-HEMT element.

When proton (H) or helium (He) is injected around the element region 12 to the depth of the GaAs substrate 24 with the element region 12 left, the inactive region 14 is formed to incur element separation.

For example, the lower electron supply layer 28 and upper electron supply layer 32 have a thickness of 500 Å. The impurity concentration of n-AlGaAs for these layers is 1×10¹⁸ cm⁻³. The channel layer 30 has a thickness of 30 to 500 Å. The Schottky layer 34 has a thickness of 50 to 500 Å. The cap layer 36 has a thickness of 200 to 2000 Å. The contact layer 38 has a thickness of 500 to 2000 Å. The impurity concentration of n-GaA for the contact layer 38 is approximately 1×10¹⁸ cm⁻³.

In the present embodiment, the active region 16, which is an active semiconductor area, is constituted by the lower electron supply layer 28, channel layer 30, upper electron supply layer 32, and Schottky layer 34. In the active region 16, a channel is formed inside of the channel layer 30 for an interface between the lower electron supply layer 28 and channel layer 30 and formed inside of the channel layer 30 for an interface between the upper electron supply layer 32 and channel layer 30. Consequently, electrons and holes flow to perform a transistor operation.

In the p-HEMT 10, an intrinsic field-effect transistor, which is formed directly below the gate electrode 18, is referred to as a first FET. If the gate-to-drain distance Lrd is increased to increase the gate-to-drain voltage withstanding capacity Vgd0 as in the p-HEMT 10, no gate electrode exists in the drain side active region 16a between the gate and drain. However, a channel, which is the same as the one existing directly below the gate electrode 18, exists. Therefore, when a charge is trapped in the cap layer 36 or on the surface of the cap layer 36, a pseudo field-effect transistor, that is, a second FET, is formed in addition to the first FET as indicated by A in FIG. 2.

FIG. 3 is a circuit diagram to show a p-HEMT equivalent circuit that is formed in consideration of a pseudo FET for the high-frequency semiconductor device according to an embodiment of the present invention.

As indicated in FIG. 3, the gate of the first FET 40 is connected to the gate electrode 18; the source of the first FET 40 is grounded via the source electrode 20; and the drain electrode of the first FET 40 is connected to drain electrode 22 via a circuit that is formed by the second FET 42 and resistors R1 and R2.

The second FET 42 is not usually depleted. It is therefore regarded as an FET that is ON. Therefore, a slight resistance is applied between the gate and drain. However, when a high-power operation is performed at a frequency as high as 14 GHz, the resulting current flow considerably exceeds the DC maximum current Imax due to the parasitic capacitance that accompanies the first FET 40.

When the conventional configuration is employed, that is, when the active region between the gate and drain has the same width as the active region between the gate and source, the second FET 42 cannot supply a current that exceeds the DC maximum current Imax. Consequently, the resistance increases to inhibit the current flow so that the output power does not increase.

In the p-HEMT 10, however, the electrode width (y-direction length) of the drain electrode 22 is greater than the gate width of the gate electrode 18 and the width (y-direction length) of the source side active region 16b, and the width (y-direction length) of the drain side active region 16a is continuously increased from the electrode width of the gate electrode 18 to the width of the drain electrode 22 in the direction from the gate electrode 18 to the drain electrode 22.

The layer structure of the active region 16 is uniform so that the drain side active region 16a and source side active region 16b have the same layer structure. Therefore, the maximum current increases in proportion to an increase in the width (y-direction length) of the active region 16. Thus, the second FET 42, which is configured in the drain side active region 16a, is capable of flowing a larger current than the first FET 40. Therefore, even when a high-power operation is performed at a frequency as high as 14 GHz, a large current can be supplied to the first FET 40 without increasing the resistance of the second FET 42. Consequently, a decrease in the output power is inhibited.

In other words, the p-HEMT 10 can inhibit the output power from decreasing without having to shorten the gate-to-drain distance Lrd. Therefore, the output power can be increased without decreasing the gate-to-drain voltage withstanding capacity Vgd0.

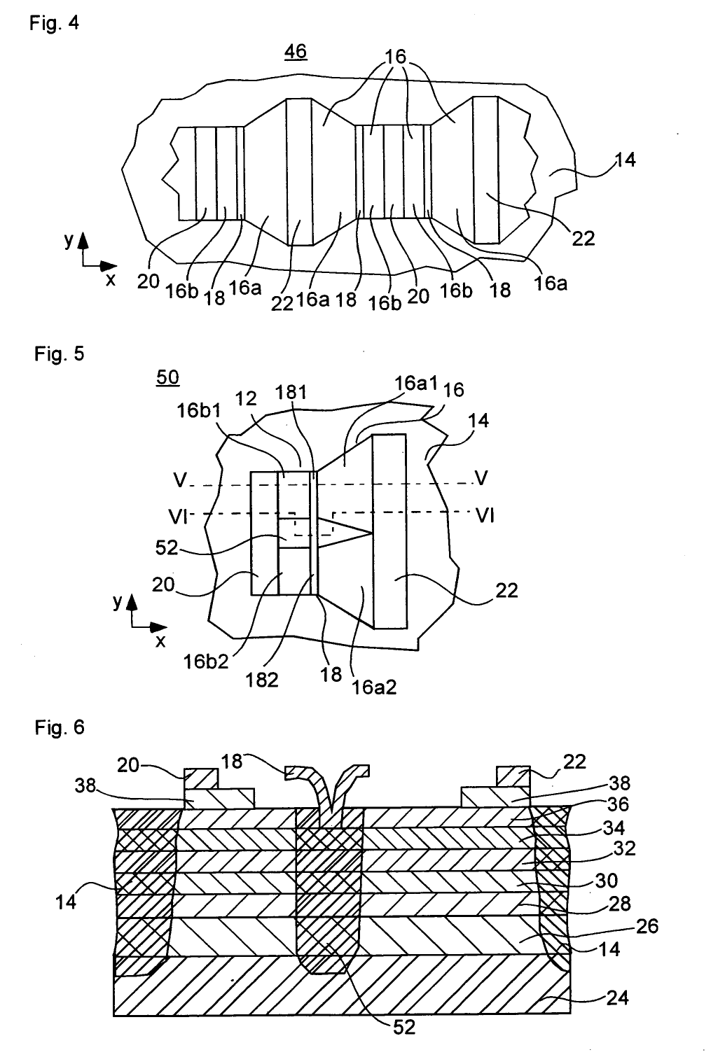

FIG. 4 is a plan view illustrating a modified version of the high-frequency semiconductor device according to one embodiment of the present invention.

FIG. 1 shows an example of one element. However, the high-frequency semiconductor device shown in FIG. 4 includes a plurality of p-HEMT elements. A plurality of p-HEMT elements are consecutively arranged to increase the output power as a rule.

A p-HEMT 46 is configured so as to share the source electrodes 20 or drain electrodes 22 of two p-HEMT elements. The source side active region 16b is positioned with the source electrode 20 used as a symmetry axis, and the drain side active region 16a is positioned with the drain electrode 22 used as a symmetry axis. In this manner, a plurality of p-HEMTs 10 are consecutively arranged.

In the case of the p-HEMT 46, too, the source resistance is decreased to increase the gate-to-drain voltage withstanding capacity Vgd0 by reducing the distance between the gate electrode 18 and source electrode 20 and by making the distance Lrd between the gate electrode 18 and drain electrode 22 longer than the distance between the gate electrode 18 and source electrode 20.

Further, the width (y-direction length) of the source side active region 16b is equal to the electrode widths of the gate electrode 18 and source electrode 20. However, the width (y-direction length) of the drain side active region 16a increases continuously from the electrode width of the gate electrode 18 to the width of the drain electrode 22 in the direction from the gate electrode 18 to the drain electrode 22.

Since a plurality of p-HEMTs 10 are consecutively arranged as described above, the p-HEMT 46 constitutes a high-frequency semiconductor device having desired output power.

In p-HEMT 10 and p-HEMT 46, the source resistance can be reduced to increase the gate-to-drain voltage withstanding capacity Vgd0 by making the gate-to-drain distance Lrd longer than the gate-to-source distance. Further, a decrease in the output power can be inhibited without decreasing the gate-to-drain voltage withstanding capacity Vgd0 by continuously increasing the width of the drain side active region from the electrode width of the gate electrode to the electrode width of the drain electrode in the direction from the gate electrode to the drain electrode. Consequently, it is possible to configure a high-frequency semiconductor device having a large voltage withstanding capacity and increased output power.

In p-HEMT 10 and p-HEMT 46, the width of the drain side active region 16a is continuously increased from the electrode width of the gate electrode 18 to the width of the drain electrode 22 in the direction from the gate electrode 18 to the drain electrode 22. Alternatively, however, the width of the drain side active region 16a may be increased step by step.

As described above, the high-frequency semiconductor device according to one embodiment of the present invention comprises a semi-insulating semiconductor substrate; an active region located on the semiconductor substrate, the active region including a channel layer composed of a conductive type semiconductor layer; a gate electrode located on the active region; and a source electrode and a drain electrode on the surface of the active region, opposed to each other with the gate electrode between the source electrode and the drain electrode; wherein the active region have a first region being a part between the gate electrode and the drain electrode, and wherein the first region has a width increasing in correspondence with a distance from the gate electrode in the direction to the drain electrode. Even if a pseudo FET generates in the first region, the above configuration causes the maximum current to increase in proportion to an increase in the width of the drain electrode in the first region, thereby a large current is supplied to an FET that is constituted by the gate electrode. Therefore, it is possible to inhibit the output power from decreasing. This makes it possible to configure a high-frequency semiconductor device having a large voltage withstanding capacity and increased output power.

Further, a plurality of source electrodes, gate electrodes, and drain electrodes are continuously arranged by sharing the source electrodes or drain electrodes and positioning the gate electrodes with the source electrodes or drain electrodes used as a symmetry axis. This makes it possible to configure a high-frequency semiconductor device having desired output power.

### Second Embodiment

FIG. 5 is a plan view illustrating a high-frequency semiconductor device according to one embodiment of the present invention. FIG. 6 is a cross-sectional view that is taken along section VI-VI of FIG. 5 to illustrate the high-frequency semiconductor device. The cross-sectional view that is taken along section V-V of FIG. 5 to illustrate the high-frequency semiconductor device is the same as FIG. 2.

As indicated in FIG. 5, a p-HEMT 50 according to the second embodiment is such that the active region 16 is divided into two segments by an inactive region 52 that is extended between the source electrode 20 and drain electrode 22. Source side active regions 16b1, 16b2 are extended between the gate electrode 18 and source electrode 20 in the x-direction without varying the width (y-direction length). However, the widths (y-direction lengths) of drain side active regions 16a1, 16a2 are continuously increased from the electrode widths of gate electrodes 181, 182 in the direction from the gate electrode 18 to the drain electrode 22.

As indicated in FIG. 2, which presents a cross-sectional view that is taken along section V-V of FIG. 5 to illustrate the high-frequency semiconductor device, the multilayer structure of the p-HEMT 50 is the same as that of the p-HEMT 10 according to the first embodiment. In the present embodiment, which is shown in FIG. 6, the inactive region 52 is formed to divide the active region 16 by injecting proton (H) or helium (He) from the cap layer 36 to the depth of the GaAs substrate 24.

When, for instance, the gate width is 200 μm and the ratio of the total width of the drain electrode 22 to the total electrode width of the gate electrode 18 increases in a situation where the width of the drain side active region 16a is continuously increased from the total electrode width of the gate electrode 18 to the total width of the drain electrode 22 in the direction from the gate electrode 18 to the drain electrode 22, a current is supplied only to an area near the periphery of the width of the drain side active region 16a so that the current is not readily supplied to the center of the width of the drain side active region 16a under certain circumstances.

In the p-HEMT 50, however, the drain side active region 16a is divided into, for example, two drain side active regions 16a1, 16a2. Therefore, the distances between the drain electrode 22 and various positions beneath the gate electrode 18 do not significantly vary. Thus, the current is supplied virtually uniformly to the drain side active region 16a. As a result, the resulting maximum operating current flow is proportional to the width of the drain side active region 16a.

Consequently, the output power can be increased efficiently in addition to the advantages provided by the p-HEMT 10 according to the first embodiment. In the present embodiment, the active region 16 is divided into two. Alternatively, however, the active region 16 may be divided into an increased number of segments.

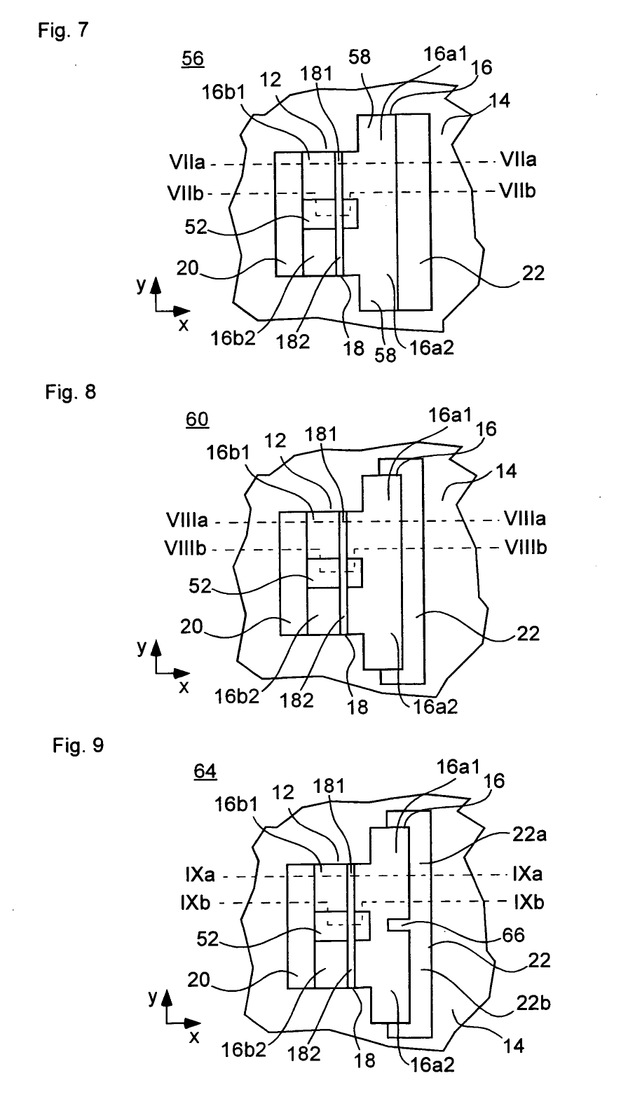

FIG. 7 is a plan view illustrating a modified version of the high-frequency semiconductor device according to one embodiment of the present invention. The cross-sectional view that is taken along section VIIa-VIIa of FIG. 7 to illustrate the high-frequency semiconductor device is the same as FIG. 2. The cross-sectional view that is taken along section VIIb-VIIb of FIG. 7 to illustrate the high-frequency semiconductor device is the same as FIG. 6.

FIG. 7 shows p-HEMT 56, which has basically the same structure as p-HEMT 50. In p-HEMT 56, however, the periphery in contact with the inactive region 14 in the drain side active region 16a and the periphery in contact with inactive region 52 are enlarged step by step in the direction from the gate electrode 18 to the drain electrode 22. Because of the use of the above configuration, the widths (y-direction lengths) of the drain side active regions 16a1, 162 are increased step by step from the electrode widths of the gate electrodes 181, 182 in the direction from the gate electrode 18 to the drain electrode 22.

In the currently used example, the widths (y-direction lengths) of the drain side active regions 16a1, 16a2 of p-HEMT 56 are increased in two steps. Alternatively, however, the widths (y-direction lengths) of the drain side active regions 16a1, 16a2 of p-HEMT 56 may be increased in an increased number of steps.

In marked contrast to p-HEMT 50 in which the widths (y-direction lengths) of the drain side active regions 16a1, 16a2 are continuously increased from the electrode widths of the gate electrodes 181, 182 in the direction from the gate electrode 18 to the drain electrode 22, a projection 58, which is a region extended out of the drain side active regions 16a1, 16a2, is formed in the modified p-HEMT 56 to enlarge the active region accordingly so that the parasitic resistance can be reduced.

Since the current flows to a region where the resistance is low, the projection 58, which is an outward extension, effectively works to increase the maximum operating current, thereby making it possible to obtain increased output power.

As described above, in the high-frequency semiconductor device according to one embodiment of the present invention, the first region of the active region is divided into a plurality of regions via an inactive region adjacent to a part of the gate electrode and extended in the gate length direction of the gate electrode, and the divided first regions has a width increasing in correspondence with a distance from the gate electrode in the direction to the drain electrode. Even when the gate width is increased, the current is supplied uniformly in the width direction of the first region so that increased output power can be efficiently obtained.

### Third Embodiment

FIG. 8 is a plan view illustrating a high-frequency semiconductor device according to one embodiment of the present invention. The cross-sectional view that is taken along section VIIIa-VIIIa of FIG. 8 to illustrate the high-frequency semiconductor device is the same as FIG. 2. The cross-sectional view that is taken along section VIIIb-VIIIb of FIG. 8 to illustrate the high-frequency semiconductor device is the same as FIG. 6.

FIG. 8 shows p-HEMT 60, which has basically the same structure as p-HEMT 56. In p-HEMT 60, however, the widths (y-direction lengths) of the drain side active regions 16a1, 16a2 are increased in two steps. In addition, p-HEMT 60 differs from p-HEMT 56 in the shape of the drain electrode 22. In other words, the drain electrode 22, which faces the-gate electrode 18, is concaved toward the gate electrode 18 when the entire drain side active region 16a is viewed. More specifically, the drain electrode 22 is a concave that has a parallel straight portion, which faces and runs parallel with the gate electrode 18, and peripheries that are perpendicularly bent at both ends of the parallel straight portion and oriented toward the gate electrode 18.

In p-HEMT 60, therefore, the length of the periphery of the drain electrode 22 that is in contact with the drain side active region 16a is increased. Thus, power can also be supplied in a lateral direction from the drain side active region 16a. Consequently, a larger current can be supplied.

In p-HEMT 60, the widths (y-direction lengths) of the drain side active regions 16a1, 16a2 are increased step by step. Alternatively, however, the widths (y-direction lengths) of the drain side active regions 16a1, 16a2 may be continuously increased while the drain electrode 22, which faces the gate electrode 18, is concaved toward the gate electrode 18 when the entire drain side active region 16a is viewed.

In p-HEMT 60, the drain side active region 16a is divided by the inactive region 52. Alternatively, however, the drain side active region 16a may continuously increase its width (y-direction length), as is the case with p-HEMT 10, from the electrode width of the gate electrode 18 to the width of the drain electrode 22 without being divided by the inactive region when the distance to the drain electrode 22 decreases while the drain electrode 22, which faces the gate electrode 18, is concaved toward the gate electrode 18 when the entire drain side active region 16a is viewed.

FIG. 9 is a plan view illustrating a modified version of the high-frequency semiconductor device according to one embodiment of the present invention. The cross-sectional view that is taken along section IXa-IXa of FIG. 9 to illustrate the high-frequency semiconductor device is the same as FIG. 2. The cross-sectional view that is taken along section IXb-IXb of FIG. 9 to illustrate the high-frequency semiconductor device is the same as FIG. 6.

FIG. 9 shows p-HEMT 64, which has basically the same structure as p-HEMT 60. The difference between p-HEMT 64 and p-HEMT 60 is described below.

In p-HEMT 60, the drain electrode 22 is concaved toward the gate electrode when the entire drain side active region 16a is viewed. In p-HEMT 64, on the other hand, the drain electrode 22 has a protrusion 66 at a place that faces the inactive region 52, and the drain electrodes 22a, 22b are concaved toward the gate electrode 18 in accordance with the drain side active regions 16a1, 16a2.

The peripheries of the drain electrodes 22a, 22b that face the gate electrodes 181, 182 include a parallel straight portion, which faces and runs parallel with the gate electrodes 181, 182, and straight portions that are perpendicularly bent at both ends of the parallel straight portion and oriented toward the gate electrodes 181, 182. Each of these peripheries is connected to the full width of the drain electrode 22 via the protrusion 66.

In p-HEMT 64, therefore, the length of the periphery of the drain electrode 22 in contact with the drain side active region 16a increases so that the current can be supplied in a lateral direction to the drain side active regions 16a1, 16a2, respectively. Consequently, a larger current can be supplied to the drain side active regions 16a1, 16a2, respectively. Further, a larger current can be supplied to the entire drain side active region 16a. Therefore, increased output power can be obtained.

The present modified embodiment is structured so that one protrusion 66 is furnished. Alternatively, however, many protrusions may be furnished to face the inactive region 52.

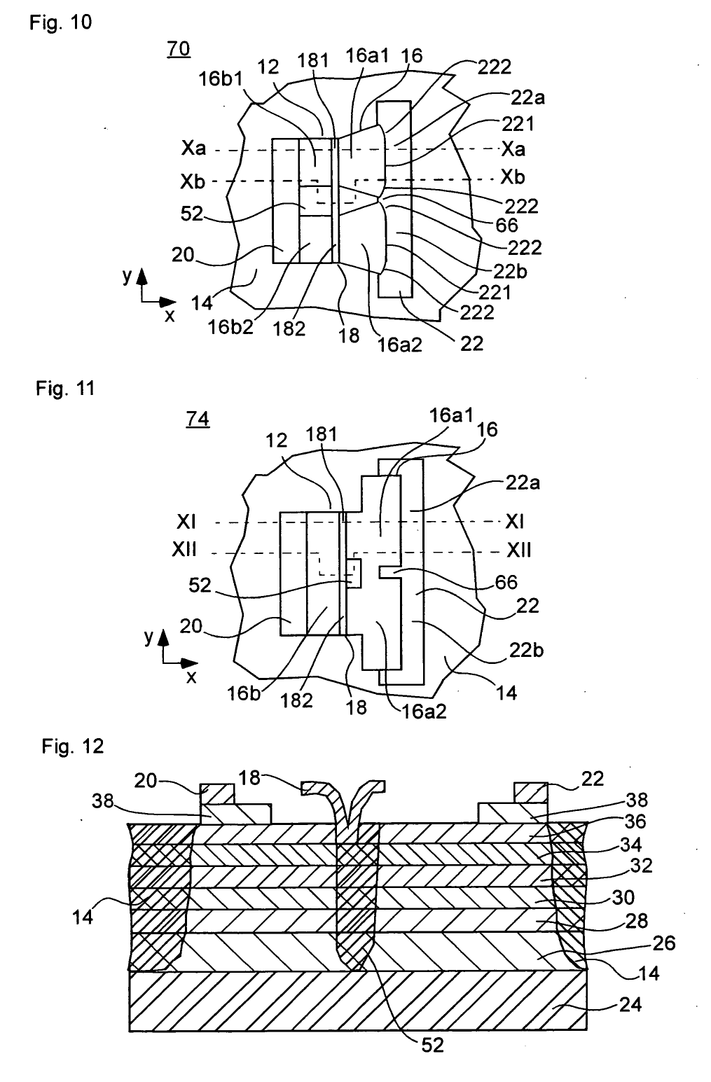

FIG. 10 is a plan view illustrating another modified version of the high-frequency semiconductor device according to one embodiment of the present invention. The cross-sectional view that is taken along section Xa-Xa of FIG. 10 to illustrate the high-frequency semiconductor device is the same as FIG. 2. The cross-sectional view that is taken along section Xb-Xb of FIG. 10 to illustrate the high-frequency semiconductor device is the same as FIG. 6.

The p-HEMT 70 shown in FIG. 10 is equal to the p-HEMT 50 according to the second embodiment in that the widths (y-direction lengths) of the drain side active regions 16a1, 16a2 are continuously increased from the electrode widths of the gate electrodes 181, 182 in the direction from the gate electrode 18 to the drain electrode 22. Further, the p-HEMT 70 shown in FIG. 10 is equal to p-HEMT 64 in that the drain electrode 22 has the protrusion 66 at a place facing the inactive region 52 and is concaved toward the gate electrode 18 in accordance with the drain side active regions 16a1, 16a2.

However, the shape of the drain electrode 22 of p-HEMT 70 differs from that of p-HEMT 60 as described below.

In p-HEMT 64, the peripheries of the drain electrodes 22a, 22b that face the gate electrodes 181, 182 include a parallel straight portion, which faces and runs parallel with the gate electrodes 181, 182, and straight portions that are perpendicularly bent at both ends of the parallel straight portion and oriented toward the gate electrodes 181, 182. Each of these peripheries is connected to the full width of the drain electrode 22 via the protrusion 66. In p-HEMT 70, however, the peripheries of the drain electrodes 22a, 22b that face the gate electrodes 181, 182 comprise a parallel straight portion 221, which faces and runs parallel with the gate electrodes 181, 182, and an arc 222 whose radius is the distance between the parallel straight portion 221 and either one of the gate electrodes 181, 182, which are connected to both ends of the parallel straight portion 221. Each of these peripheries is connected to the full width of the drain electrode 22 via the protrusion 66.

Since p-HEMT 70 is configured as described above, the distances between the drain electrodes 22a, 22b and various places directly below the gate electrodes 181, 182 are constant. Thus, the distance between the gate and drain electrodes is uniform. Therefore, the current is uniformly supplied from the drain electrode 22, and the voltage withstanding capacity Vgd0 is uniform within the active region 16. Consequently, the current is uniformly supplied within the active region 16 so that the obtained maximum operating current is proportional to the width of the active region 16. As a result, increased output power can be obtained.

Further, the voltage withstanding capacity does not unevenly deteriorate within the active region 16. Therefore, the voltage withstanding capacity is enlarged to permit high-voltage operations. Thus, increased output power is obtained.

FIG. 11 is a plan view illustrating still another modified version of the high-frequency semiconductor device according to one embodiment of the present invention.

FIG. 12 is a cross-sectional view that is taken along section XII-XII of FIG. 11 to illustrate the high-frequency semiconductor device. The cross-sectional view that is taken along section XI-XI of FIG. 11 to illustrate the high-frequency semiconductor device is the same as FIG. 2.

FIGS. 11 and 12 show p-HEMT 74, which has basically the same structure as p-HEMT 64. The difference between p-HEMT 74 and p-HEMT 64 is described below.

The inactive region 52 of p-HEMT 64 is extended on both sides of the gate electrode 18, that is, extended on both sides of the drain side active region 16a and source side active region 16b. This inactive region 52 divides both the drain side active region 16a and source side active region 16b into two segments. On the other hand, the inactive region 52 of p-HEMT 74 is extended in the drain side active region 16a only so that the drain side active region 16a is divided into drain side active regions 16a1 and 16a2. However, the inactive region 52 is not positioned in the source side active region 16b, and the source side active region 16b is not divided.

In p-HEMT 74, therefore, the width of the source side active region 16b is increased so that the parasitic resistance Rs between the gate and source is reduced. Consequently, in p-HEMT 74, the resistance-induced loss is reduced so that increased output power is obtained.

In the high-frequency semiconductor device according to one embodiment of the present invention, one side of the drain electrode facing the gate electrode is concaved toward the gate electrode as described above. Therefore, the length of the drain electrode periphery in contact with the drain side active region is increased. Thus, a larger current can be supplied to the drain side active region. This makes it possible to configure a high-frequency semiconductor device that offers increased output power.

Further, since one side of the drain electrode, which faces the gate electrode, is concaved toward the gate electrode in accordance with the divided first regions, the length of the drain electrode periphery in contact with the drain side active region is increased. Therefore, a larger current can be supplied to the drain side active regions. Further, since the entire drain side active region can supply a larger current, it is possible to obtain increased output power.

When the p-HEMT described in conjunction with the second or third embodiment is configured so as to share the source electrodes or drain electrodes and position the gate electrodes with the source or drain electrodes used as a symmetry axis as is the case with the p-HEMT 46 shown in FIG. 4, a plurality of source electrodes, gate electrodes, and drain electrodes can be consecutively arranged to configure a high-frequency semiconductor device having desired output power.

### Fourth Embodiment

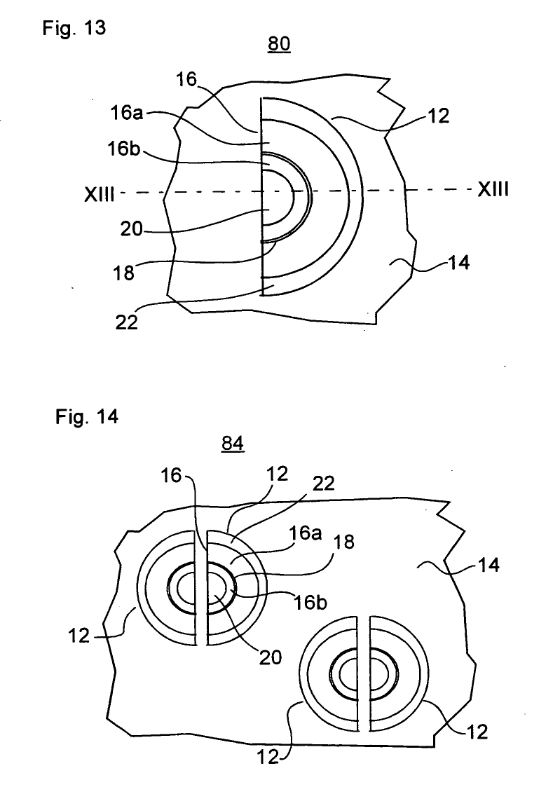

FIG. 13 is a plan view illustrating a high-frequency semiconductor device according to one embodiment of the present invention. The cross-sectional view that is taken along section XIII-XIII of FIG. 13 to illustrate the high-frequency semiconductor device is the same as FIG. 2.

As shown in FIG. 13, a p-HEMT 80 has a circular planar shape. In the present embodiment, it has a semicircular planar shape. The source electrode 20 is positioned at the center of the active region 16. The source side active region 16b, gate electrode 18, drain side active region 16a, and drain electrode 22 are positioned sequentially and concentrically around the source electrode 20. The configuration of p-HEMT 80 is similar to those of the aforementioned p-HEMTs in that the distance between the gate electrode 18 and source electrode 20 is reduced, and that the distance Lrd between the gate electrode 18 and drain electrode 22 is longer than the distance between the gate electrode 18 and source electrode 20. It means that p-HEMT 80 is configured to enlarge the gate-to-drain voltage withstanding capacity Vgd0 while reducing the source resistance.

In p-HEMT 80, the drain electrode 22 is positioned outside the gate electrode 18. Therefore, the drain electrode width (the circumferential length in the present embodiment) is greater than the gate width (the circumferential length in the present embodiment) in proportion to the radius. In other words, the width of the drain side active region 16a (circumferential length) is continuously increased from the electrode width of the gate electrode 18 to the width of the drain electrode 22 in the direction from the gate electrode 18 to the drain electrode 22, that is, as the distance to the drain electrode 22 decreases. In addition, the layer structure of p-HEMT 80 is the same as that of p-HEMT 10. Therefore, the same advantages are provided as is the case with the first embodiment.

In p-HEMT 80, the distance between the gate end and drain electrode 22 is constant at various positions of the drain side active region 16a directly below the gate and at all gate width positions. In other words, the distance between the gate end and drain electrode 22 is uniform.

Therefore, a uniform current is supplied from the drain electrode 22 to the drain side active region 16a so that the resulting maximum operating current is proportional to the width (that is, the circumferential length) of the drain side active region 16a. Thus, increased output power can be obtained.

Further, the voltage withstanding capacity can be increased because it does not decrease in the drain side active region 16a. Consequently, the operation can be performed at a higher voltage. In addition, increased output power can be obtained.

FIG. 14 is a plan view illustrating a high-frequency semiconductor device according to one embodiment of the present invention.

FIG. 14 shows p-HEMT 84, which is configured so that a plurality of p-HEMTs 80 are used. For p-HEMT 84, which uses a plurality of p-HEMTs 80, it is necessary to use air bridge or other similar wiring to make electrode connections. However, it is possible to configure a high-frequency semiconductor device having desired output power.

In the present embodiment, p-HEMT 80 is semicircular. Alternatively, however, it may be in any shape as far as it is circular.

As described above, in the high-frequency semiconductor device according to one embodiment of the present invention, the gate electrode and drain electrode are positioned on the surface of the active region with the planar shape of the gate electrode and drain electrode being a part of a circular ring, and the source electrode, gate electrode, and drain electrode are arranged so that the gate electrode and drain electrode are positioned concentrically around the source electrode. The use of this configuration makes it possible to provide an increased voltage withstanding capacity and increase the maximum operating current. In addition, the output power can be increased.

Although the foregoing description assumes the use of a p-HEMT, the same advantages are provided even when a MESFET or other field-effect transistor is used.

As described above, the high-frequency semiconductor device according to the present invention is suitable for use as a power amplifier that operates in a 3 GHz or higher frequency band and serves a wireless communication system for satellite communications, terrestrial microwave communications, or the like.

While the presently preferred embodiments of the present invention have been shown and described. It is to be understood these disclosures are for the purpose of illustration and that various changes and modifications may be made without departing from the scope of the invention as set forth in the appended claims.

1. A semiconductor device operating at frequency between 0.8 GHz and 300 GHz and comprising:
a semi-insulating semiconductor substrate;
an active region located on the semiconductor substrate, the active region including a channel layer composed of a conductive semiconductor layer;
a gate electrode located on the active region; and
a source electrode and a drain electrode on the surface of the active region, opposed to each other with the gate electrode between the source electrode and the drain electrode wherein
the active region includes a first region between the gate electrode and the drain electrode, and
the first region has a width increasing in correspondence with distance from the gate electrode in the direction of the drain electrode.

2. The semiconductor device according to claim 1, wherein
the first region of the active region is divided into a plurality of regions via an inactive region adjacent to a part of the gate electrode and extending in the gate length direction of the gate electrode; and
the plurality of first regions has a width increasing in correspondence with distance from the gate electrode in the direction of the drain electrode.

3. The semiconductor device according to claim 1, wherein the width of the first region increases continuously.

4. The semiconductor device according to claim 1, wherein the width of the first region increases step-by-step.

5. The semiconductor device according to claim 2, wherein the width of the plurality of first regions increases continuously.

6. The semiconductor device according to claim 2, wherein the width of the plurality of first regions increases step-by-step.

7. The semiconductor device according to claim 1, wherein a side of the drain electrode, which faces the gate electrode is concave toward the gate electrode.

8. The semiconductor device according to claim 5, wherein a side of the drain electrode- which faces the gate electrode is concave toward the gate electrode in accordance with the divided first regions.

9. The semiconductor device according to claim 1, including a plurality of source electrodes, gate electrodes, and drain electrodes, continuously arranged by sharing the source electrodes or the drain electrodes and the gate electrodes are positioned so that the source electrodes or the drain electrodes have an axis of symmetry.

10. The semiconductor device according to claim 1, wherein
the gate electrode and drain electrode are positioned on the surface of the active region with the gate electrode and drain electrode having shapes, in plan view, that are parts a circular ring, and
the source electrode, the gate electrode, and the drain electrode are arranged so that the gate electrode and the drain electrode are positioned concentrically around the source electrode.

11. The semiconductor device according to claim 1, wherein gate electrode-to-drain electrode distance is greater than gate electrode-to-source electrode distance.
